(19) United States
(12) Patent Application Publication
(10) Pub. No.: US 2021/0036685 A1
(43) Pub. Date: Feb. 4, 2021

(54) INTEGRATED FILTER STACK FOR A RADIO FREQUENCY (RF) FRONT-END MODULE (FEM)

(71) Applicant: Intel Corporation, Santa Clara, CA (US)

(72) Inventors: Telesphor Kamgaing, Chandler, AZ (US); Feras Eid, Chandler, AZ (US); Georgios Dogiamis, Chandler, AZ (US); Aleksandar Aleksov, Chandler, AZ (US); Johanna M. Swan, Scottsdale, AZ (US)

(73) Assignee: Intel Corporation, Santa Clara, CA (US)

(21) Appl. No.: 16/526,672

(22) Filed: Jul. 30, 2019

(51) Int. Cl. H03H 9/205; H03F 3/24; H03H 9/25; H01L 41/053; H03H 9/64; H03H 9/54; H01L 25/10; H01L 23/10; H01L 23/552

(52) U.S. Cl. CPC H03H 9/205; H03F 3/24; H03H 9/25; H01L 41/0533; H03H 9/64; H04B 1/005; H01L 25/10; H01L 23/10; H01L 23/552; H03F 2200/294; H03F 2200/451; H03H 9/54

(57) ABSTRACT

Embodiments may relate to a radio frequency (RF) front-end module (FEM) that includes a first acoustic wave resonator (AWR) die coupled with a package substrate. The RF FEM may also include a second AWR die coupled with the first AWR die. The first AWR die may be between the package substrate and the second AWR die. Other embodiments may be described or claimed.

### BACKGROUND

Form factor reduction and performance improvement may be considered to be important elements for the next generation of mobile and wireless communication devices and platforms. User terminal devices and network access points may be expected to support multiple frequency bands that utilize different filters.

### BRIEF DESCRIPTION OF THE DRAWINGS

FIG. 1 depicts a simplified example top down view of a radio frequency (RF) front-end module (FEM) that includes a filter stack, in accordance with various embodiments.

FIG. 2 depicts a simplified example cross-sectional view of the RF FEM of FIG. 1, in accordance with various embodiments.

FIG. 3 depicts a simplified example cross-sectional view of a filter stack, in accordance with various embodiments.

FIG. 4 depicts an example technique for the manufacture of a RF FEM that includes a filter stack, in accordance with various embodiments.

FIG. 5 illustrates an example of infrastructure equipment, in accordance with various embodiments.

FIG. 6 illustrates an example of a computer platform, in accordance with various embodiments.

FIG. 7 illustrates example components of baseband circuitry and a RF FEM, in accordance with various embodiments.

FIG. 8 is a block diagram of an example electrical device that may include a RF FEM with a filter stack, in accordance with various embodiments.

### DETAILED DESCRIPTION

In the following detailed description, reference is made to the accompanying drawings which form a part hereof, wherein like numerals designate like parts throughout, and in which is shown by way of illustration embodiments in which the subject matter of the present disclosure may be practiced. It is to be understood that other embodiments may be utilized and structural or logical changes may be made without departing from the scope of the present disclosure. Therefore, the following detailed description is not to be taken in a limiting sense.

For the purposes of the present disclosure, the phrase “A or B” means (A), (B), or (A and B). For the purposes of the present disclosure, the phrase “A, B, or C” means (A), (B), (C), (A and B), (A and C), (B and C), or (A, B and C).

The description may use perspective-based descriptions such as top/bottom, in/out, over/under, and the like. Such descriptions are merely used to facilitate the discussion and are not intended to restrict the application of embodiments described herein to any particular orientation.

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or elements are in direct contact.

In various embodiments, the phrase “a first feature [[formed/deposited/disposed/etc.]] on a second feature,” may mean that the first feature is formed/deposited/disposed/etc. over the feature layer, and at least a part of the first feature may be in direct contact (e.g., direct physical or electrical contact) or indirect contact (e.g., having one or more other features between the first feature and the second feature) with at least a part of the second feature.

Various operations may be described as multiple discrete operations in turn, in a manner that is most helpful in understanding the claimed subject matter. However, the order of description should not be construed as to imply that these operations are necessarily order dependent.

As used herein, the term “module” may refer to, be part of, or include an application-specific integrated circuit (ASIC), an electronic circuit, a processor (shared, dedicated, or group) or memory (shared, dedicated, or group) that execute one or more software or firmware programs, a combinational logic circuit, or other suitable components that provide the described functionality.

Embodiments herein may be described with respect to various Figures. Unless explicitly stated, the dimensions of the Figures are intended to be simplified illustrative examples, rather than depictions of relative dimensions. For example, various lengths/widths/heights of elements in the Figures may not be drawn to scale unless indicated otherwise. Additionally, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined, e.g., using scanning electron microscopy (SEM) images or transmission electron microscope (TEM) images. In such images of real structures, possible processing defects could also be visible, e.g., not-perfectly straight edges of materials, tapered vias or other openings, inadvertent rounding of corners or variations in thicknesses of different material layers, occasional screw, edge, or combination dislocations within the crystalline region, and/or occasional dislocation defects of single atoms or clusters of atoms. There may be other defects not listed here but that are common within the field of device fabrication.

As noted above, handheld terminals, user terminal devices and network access points may be expected to support multiple frequency bands. Respective ones of the frequency bands may be associated with a different filter. Embodiments herein relate to an acoustic wave resonator (AWR) filter architecture which may reduce the overall form factor within the handheld devices, user terminals or network access points through three-dimensional (3D) stacking of AWR filters. Specifically, embodiments may relate to stacking the AWR dies to reduce the package footprint. Additionally, stacking of AWR filters may provide a quasi-monolithic integration of the AWR filters.

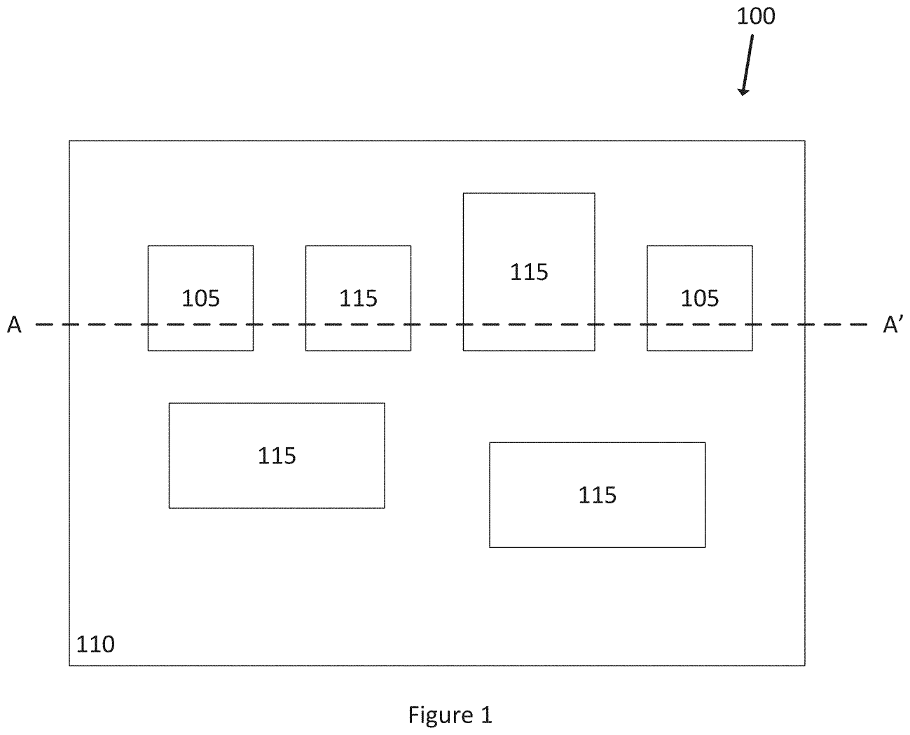

FIG. 1 depicts a simplified example top down view of a RF FEM 100 that includes a filter stack 105, in accordance with various embodiments. The RF FEM 100 may include a package substrate 110. The package substrate 110 may be, for example, considered to be a cored or coreless substrate. The package substrate 110 may include one or more layers of a dielectric material which may be organic or inorganic. The package substrate 110 may further include one or more conductive elements such as vias, pads, traces, microstrips, striplines, etc. The conductive elements may be internal to, or on the surface of, the package substrate. Generally, the conductive elements may allow for the routing of signals through the package substrate 110, or between elements that are coupled to the package substrate 110. In some embodiments the package substrate 110 may be, for example, a printed circuit board (PCB), an interposer, a motherboard, or some other type of substrate.

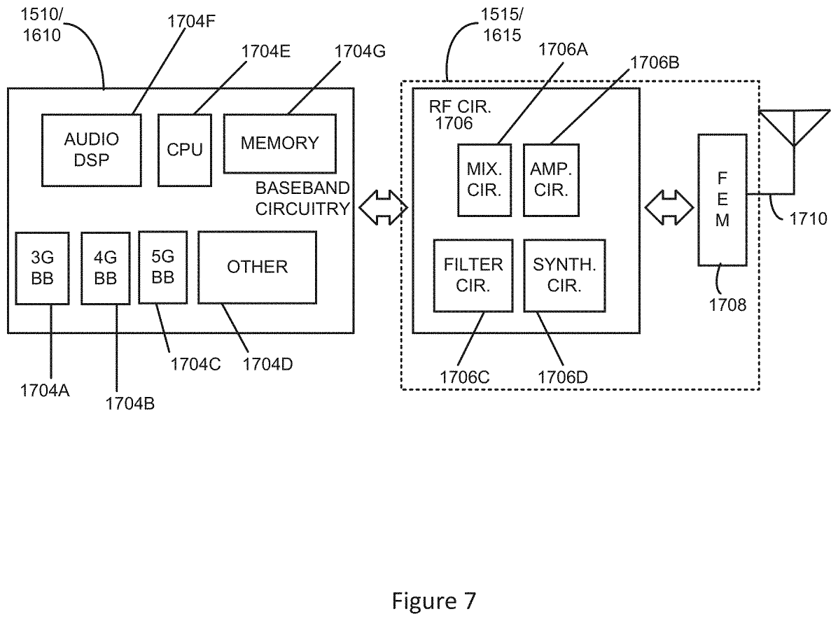

The RF FEM 100 may further include a number of active dies 115 coupled with the package substrate. An active die 115 may be, for example, a power amplifier (PA), a low-noise amplifier (LNA), a switch, logic circuitry, matching circuitry, etc. In some embodiments the active die 115 may be mixer circuitry, amplifier circuitry, synthesizer circuitry, or some other type of circuitry as discussed below with respect to FIG. 7. It will be understood that the depiction of FIG. 1 is intended as an example depiction of one embodiment of the RF FEM 100, and other embodiments may include a different number of active dies 115. As shown, the active dies 115 may be different shapes or sizes from one another. In some embodiments the active dies 115 may not be generally square-shaped or rectangular, but rather they may have some other shape such as circular, triangular, trapezoidal, irregular, etc.

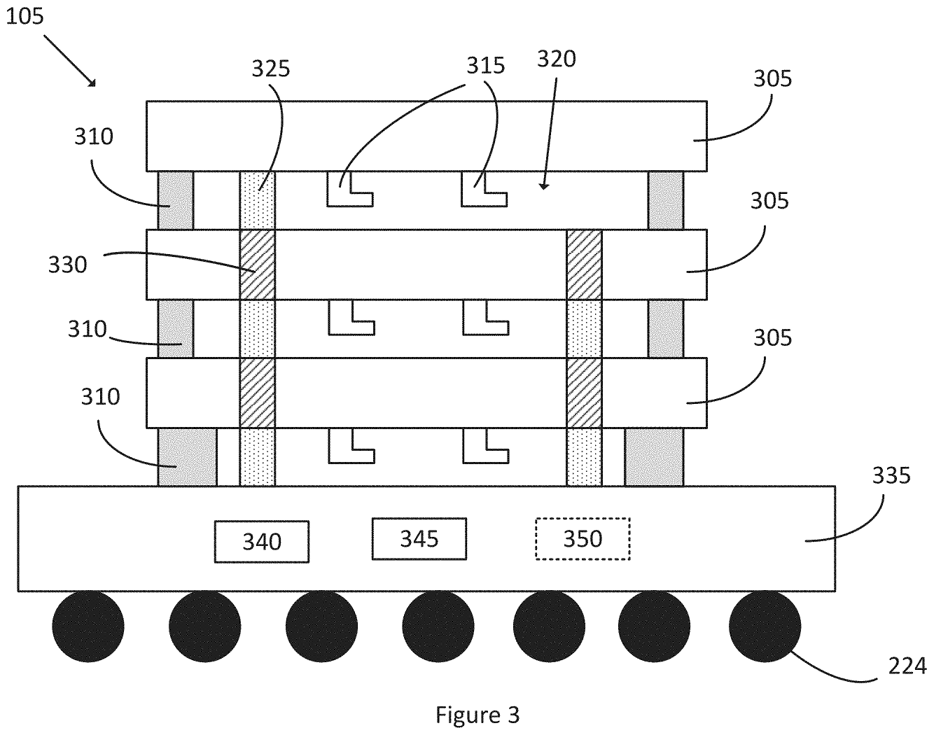

The RF FEM 100 may further include one or more filter stacks 105, as will be described in further detail below with respect to FIG. 3. Similarly to the active die 115, it will be understood that in other embodiments the RF FEM 100 may include more or fewer filter stacks, or filter stacks in a different arrangement than depicted in FIG. 1. Additionally, the filter stacks 105 may be a different size or shape than one another, or a different size or shape than depicted in FIG. 1. Other variations may be present in other embodiments.

In some embodiments the RF FEM 100 may include additional elements than those depicted in FIG. 1. For example, the RF FEM 100 may generally be considered to primarily depict elements of the RF circuitry 1706 of FIG. 7. However, in some embodiments the RF FEM 100 may include additional elements such as FEM circuitry 1708 of FIG. 7. In some embodiments the RF FEM 100 may include additional surface mount devices such as capacitors, resistors, inductors, etc. which are not shown for the sake of lack of clutter of the Figure.

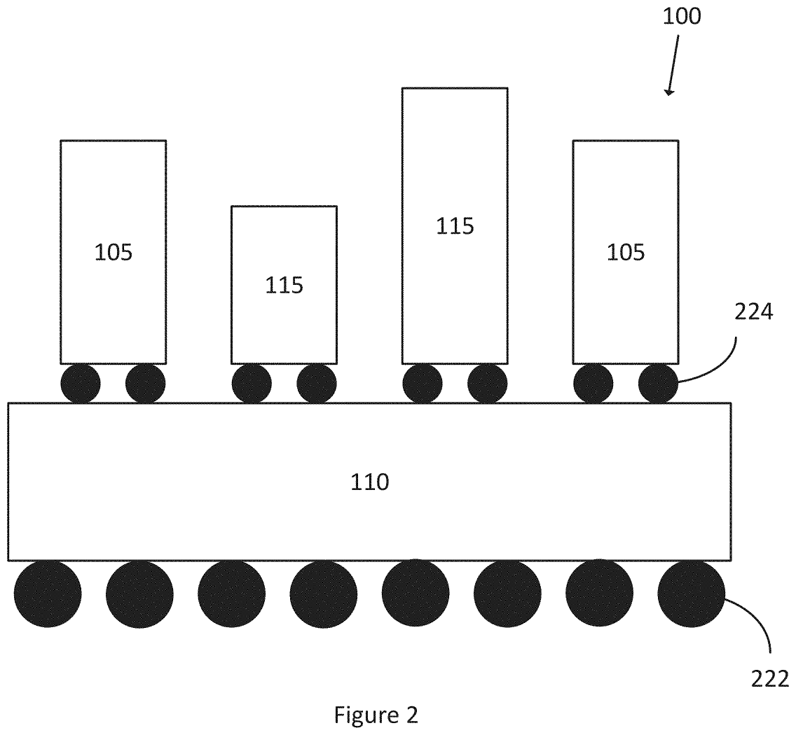

FIG. 2 depicts a simplified example cross-sectional view of the RF FEM 100 of FIG. 1, in accordance with various embodiments. Specifically, FIG. 2 may be considered to be a cross-section along line A-A′ of FIG. 1. As can be seen, in some embodiments the filter stacks 105 and the active dies 115 may be differently sized than one another. In other embodiments, various of the filter stacks 105 or the active dies 115 may be the same size as another of the filter stacks 105 or the active dies 115.

As can be seen, the filter stacks 105 and the active dies 115 may be coupled with the package substrate by one or more interconnects 224. In some embodiments, the interconnects 224 may be solder bumps such as are depicted in FIG. 1. In this embodiment, the solder bumps may be elements of a ball grid array (BGA) architecture. In other embodiments, the interconnects 224 may be, for example, pins of a pin grid array (PGA), contacts of a land grid array (LGA), contacts of a solder grid array (SGA), contacts where physical coupling is achieved using a socket architecture, a wirebond, or some other type of interconnect. Similarly, the package substrate 110 may have a number of interconnects 222 coupled thereto. Similarly to interconnects 224, the interconnects 222 may be elements of a BGA (as depicted), PGA, LGA, a socket architecture, etc. The interconnects 222 may be to, for example, coupled the RF FEM 100 to an architecture of a computing system such as a PCB, an interposer, a motherboard, etc.

It will be understood that generally the interconnects 224 may be smaller than the interconnects 222, as shown. However, in other embodiments interconnects 224 may be larger than, or the same size as, interconnects 222. Additionally, in some embodiments there may be more or fewer interconnects 222 or 224 than are shown in FIG. 1. Other variations may be present in other embodiments.

FIG. 3 depicts a simplified example cross-sectional view of a filter stack 105, in accordance with various embodiments. The filter stack 105 may include a plurality of AWR dies 305. In embodiments, the AWR dies 305 may also be referred to as “AWRs,” “resonators,” or “resonator dies.” Generally, the AWR dies 305 may be a die that includes a type of resonator such as a surface acoustic wave (SAW) resonator, a thin-film bulk acoustic resonator (FBAR), a contour mode resonator (CMR) or some other resonator. The AWR dies 305 of FIG. 3 are depicted as FBARs, but it will be understood that in other embodiments one or more of the AWR dies 305 may be some other type of resonator as discussed above.

In embodiments, various ones of the AWR dies 305 may correspond with a different RF frequency band. For example, the topmost AWR die 305 may correspond with a first RF frequency band, the middle AWR die 305 may correspond with a second RF frequency band, and the bottom-most AWR die 305 may correspond with a third RF frequency band. The various RF frequency bands may or may not overlap one another to some degree. In this way, one AWR die 305 could be used for a frequency band which may correspond to, for example, Wi-Fi communication. Another AWR die 305 could be used for a frequency band which may correspond to, for example, fourth generation (4G) telecommunication. Another AWR die 305 could be used for a frequency band which may correspond to, for example, fifth generation (5G) telecommunication, etc. In some embodiments one AWR die 305 may correspond to one frequency band related to, for example, 4G telecommunication while another AWR die 305 may correspond to another frequency band that is related to 4G telecommunication. It will be understood that these are just example variations and other variations may be present in other embodiments.

The AWR dies 305 may be stacked as shown in FIG. 3 such that adjacent AWR dies 305 form a cavity 320. A resonating element 315 of an AWR die 305 may be positioned in the cavity 320. Generally, it may be desirable for the resonating element 315 to be protected from ambient conditions such as heat or humidity. Therefore, a connective element such as a seal 310 may be present near a periphery of two adjacent AWR dies 305 as shown. The seal 310 may be, for example, metal, silicon, silicon nitride, or some other material which may hermetically seal the cavity 320. As used herein, a “hermetic seal” may be a seal which makes the cavity 320 airtight so that ambient conditions external to the filter stack 105 may not affect the resonating elements 315. In some embodiments, the seal 310 may also provide electromagnetic (EM) protection for the AWR dies 305 or the resonating elements 315.

The AWR dies 305 may additionally be communicatively coupled as shown. For example, the AWR dies 305 may be communicatively coupled by a conductive element 325 that extends between adjacent AWR dies 305. The conductive element 325 may, for example, be a signal bump or some active or passive connector that allows a data signal to pass between adjacent AWR dies 305. In some embodiments, the conductive element 325 may passively allow the data signal to transfer from one AWR die 305 to another, while in other embodiments the conductive element 325 may have some form of circuitry or other active element which may process, amplify, or otherwise alter the data signal in some form between adjacent AWR dies 305. In some embodiments the conductive element 325 may additionally or alternatively act as a power or ground connector which may couple an AWR die 305 to a power source or to ground.

The AWR dies 305 may additionally include one or more vias 330. The vias 330 may be, for example, through substrate vias (TSVs). The vias 330 may be formed of or include a conductive material such as copper, gold, etc. which may facilitate the transmission of the data signal, power, or ground through a given AWR die 305 from one conductive element 325 to another.

In various embodiments, the AWR dies 305 may include one or more conductive elements such as traces, pads, striplines, microstrips, etc. which are not shown in FIG. 3 for the sake of reduction of clutter of the Figure. The conductive elements of the AWR dies 305 may be communicatively or physically coupled with the vias 330 or the conductive elements 325, thereby allowing the data signal, the power, or the ground to be provided to an AWR die 305 that is not at the top of the filter stack 105. For example, as can be seen, a signal path of conductive elements 325 and vias 330 may terminate at the topmost AWR die 305 of the filter stack 105 (as seen on the left side of the Figure) or the middle AWR die 305 of the filter stack 105 (as seen on the right side of the Figure).

Generally, the AWR dies 305 may be coupled with one another through a wafer-to-wafer bonding technique. That is, a plurality of AWR dies 305 may be manufactured together in a wafer, and the two wafers may be coupled with one another such that individual AWR dies 305 of one wafer are coupled with individual AWR dies 305 of the other wafer. The process may be repeated to form a wafer stack that includes a plurality of AWR dies 305. The coupled AWR dies 305 may then be diced or singulated.

The filter stack 105 may further include a lid 335 which may be adjacent to the bottom-most AWR die 305. Specifically, the lid 335 may be coupled with the interconnects 224 so that when the filter stack 105 is coupled with the package substrate 110, the lid 335 may be between the AWR dies 305 and the package substrate 110. In contrast to the wafer-to-wafer bonding technique discussed above with respect to the AWR dies 305, the lid 335 and the AWR dies 305 may be coupled to one another through a die-to-wafer bonding technique. For example, after the coupled AWR dies 305 are singulated or diced, a stack that includes a plurality of AWR dies 305 may be coupled with the lid 335 through a die-to-wafer process. Specifically, the lid 335 may be formed in a wafer that includes a plurality of lids. A plurality of stacks of AWR dies 305 may be coupled with individual lids 335, and then the lids 335 may be diced or singulated from the wafer to form the filters stack 105.

Generally, the lid 335 may help to further provide a hermetic seal or provide EM protection to the AWR dies 305 or the resonating elements 315 thereof. For example, in some embodiments the lid 335 may be formed of a non-organic or non-polymer material such as metal, ceramic, silicon, silicon nitride, etc. In some embodiments the lid 335 may include one or more conductive element as described above such as pads, vias, traces, striplines, microstrips, etc. The conductive elements may allow electrical communication between one element that is coupled to or at least partially within the lid 335 and another element that is coupled to or at least partially within the lid 335. These conductive elements are not shown for the sake of lack of clutter of the Figure. As can be seen in FIG. 3, in some embodiments the seal 310 that couples the lid 335 to an AWR die 305 may be larger than the seal 310 that couples one AWR die 305 to another. However, in other embodiments the seal 310 between the lid 335 and an AWR die 305 may be the same size as, or smaller than, the seal 310 between two AWR dies 305.

In some embodiments the lid 335 may be a “passive” lid. That is, in some embodiments the lid 335 may include one or more passive elements 340 which may be, for example, a capacitor, a resistor, an inductor, etc. The lid 335 may also include one or more inductors 345. Generally, the inductors 345 within the lid 335 may have a relatively low Q value on the order of between approximately 5 and approximately 30. Generally, the inductors 345 may be used for signal matching of a signal between the interconnects 224 and an AWR die 305 to which the inductor 345 is coupled. Additionally or alternatively, the inductors 345 may serve as a termination for an electrical circuit that includes an AWR die 305. Although only a single passive element 340 and a single inductor 345 are shown in FIG. 3, in some embodiments the lid 335 may include a plurality of passive elements 340 or inductors 345. For example, in some embodiments an individual AWR die 305 may be coupled with one or more passive elements 340 or one or more inductors 345 that have values that are tuned for use with the AWR die 305.

In some embodiments the lid 335 may further include one or more active elements 350. The active elements 350 are depicted with dashed lines as they may be considered optional in some embodiments. As one example, as noted in FIG. 1, the RF FEM 100 may include one or more active dies 115. The active dies 115 may include one or more switches. In some embodiments, the lid 335 may additionally or alternatively include one or more switches or some other active element. For example, the active element 350 may be an inductor-select switch which may selectively communicatively couple an AWR die 305 with a given inductor 345. In some embodiments, the active element 350 may be a band-select switch which may selectively communicatively couple one or more of the interconnects 224 with a given AWR die 305 based on a frequency of a signal that is being transmitted between the AWR die 305 and the interconnect 224. In other embodiments, the active element 350 may be some other type of active element.

It will be understood that the embodiments depicted in FIGS. 1-3 are intended as example embodiments, and other embodiments may include one or more variations from the Figures. For example, the filter stack 105 may include more or fewer AWR dies 305, AWR dies that are differently sized from one another, etc. As noted, various of the elements such as the lid 335, the AWR dies 305, the package substrate 110, etc. may include additional active, passive, or conductive elements which are not depicted in the Figures for the sake of reduction of clutter. Various of the elements may be differently sized than are depicted, and, unless otherwise discussed, the relative sizes of various elements should not be inferred based on dimensions shown in the Figures. In some embodiments one or more of the vias 330 or the conductive elements 325 may be positioned external to the cavity 320 rather than within the cavity 320. In some embodiments the above-described wafer-to-wafer or die-to-wafer techniques may be altered from the techniques above. For example, AWR dies 305 may be coupled with one another through a die-to-die or die-to-wafer technique. One or more AWR dies 305 may be coupled with a lid 335 through a die-to-die or wafer-to-wafer technique. In some embodiments, a given lid 335 may include more than one set of vertically stacked AWR dies 305. Other variations may be present in other embodiments.

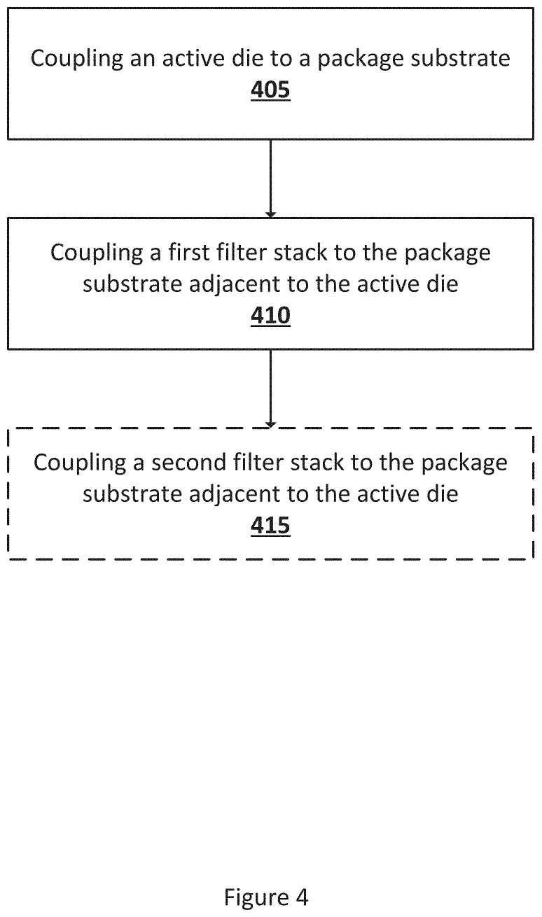

FIG. 4 depicts an example technique for the manufacture of a RF FEM that includes a filter stack, in accordance with various embodiments. The technique may include coupling, at 405, an active die to a package substrate. The active die may be similar to, and share one or more characteristics of, active die 115. The package substrate may be similar to, and share one or more characteristics of, package substrate 110.

The technique may further include coupling, at 410, a first filter stack to the package substrate adjacent to the active die. The filter stack may be similar to, and share one or more characteristics of, filter stack 105. Specifically, the filter stack may include a plurality of AWR dies (e.g., AWR dies 305) that are vertically stacked such that when the filter stack is coupled with the package substrate one AWR die is between the package substrate and another AWR die. In some embodiments the filter stack may include a lid such as lid 335.

The technique may, optionally, further include coupling, at 415, a second filter stack to the package substrate adjacent to the active die. The second filter stack may be similar to, for example, filter stack 105. In this embodiment the resultant RF FEM may have a plurality of filter stacks such as RF FEM 100. However, it will be understood that in other embodiments element 415 may not occur and the RF FEM 100 may only have a single filter stack.

It will be understood that the technique of FIG. 4 is intended as a simplified example, and in other embodiments the technique may vary. In some embodiments element 410 may occur prior to, or concurrently with, element 405. Similarly, in some embodiments elements 410 and 415 may occur concurrently. Other embodiments may have additional elements which may not be depicted in FIG. 4.

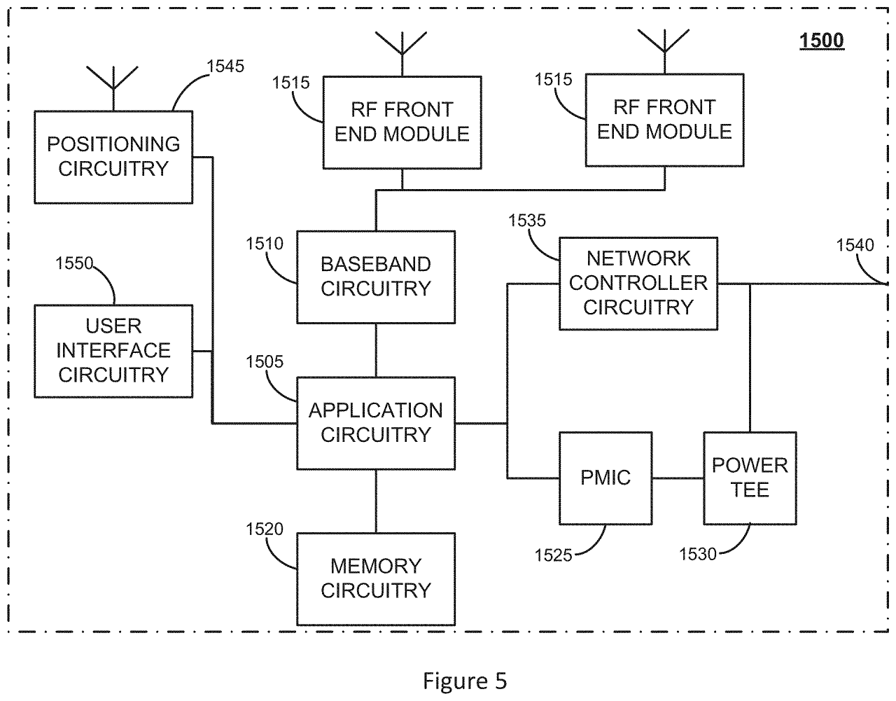

FIG. 5 illustrates an example of infrastructure equipment 1500 in accordance with various embodiments. The infrastructure equipment 1500 (or “system 1500”) may be implemented as a base station, radio head, radio access network (RAN) node, etc. In other examples, the system 1500 could be implemented in or by a user equipment (UE), application server(s), or some other element/device discussed herein. The system 1500 may include one or more of application circuitry 1505, baseband circuitry 1510, one or more RF FEMs 1515 (which may be similar to, and share one or more characteristics of, RF FEM 100), memory 1520, power management integrated circuitry (PMIC) 1525, power tee circuitry 1530, network controller 1535, network interface connector 1540, satellite positioning circuitry 1545, and user interface 1550. In some embodiments, the platform 1600 may include additional elements such as, for example, memory/storage, display, camera, sensor, or input/output (I/O) interface. In other embodiments, the components described below may be included in more than one device (e.g., said circuitries may be separately included in more than one device for Cloud-RAN (C-RAN) implementations).

As used herein, the term “circuitry” may refer to, is part of, or includes hardware components such as an electronic circuit, a logic circuit, a processor (shared, dedicated, or group) and/or memory (shared, dedicated, or group), an ASIC, a field-programmable device (FPD) (for example, a field-programmable gate array (FPGA), a programmable logic device (PLD), a complex PLD (CPLD), a high-capacity PLD (HCPLD), a structured ASIC, or a programmable System on Chip (SoC)), digital signal processors (DSPs), etc., that are configured to provide the described functionality. In some embodiments, the circuitry may execute one or more software or firmware programs to provide at least some of the described functionality. In addition, the term “circuitry” may also refer to a combination of one or more hardware elements (or a combination of circuits used in an electrical or electronic system) with the program code used to carry out the functionality of that program code. In these embodiments, the combination of hardware elements and program code may be referred to as a particular type of circuitry.

The terms “application circuitry” and/or “baseband circuitry” may be considered synonymous to, and may be referred to as “processor circuitry.” As used herein, the term “processor circuitry” may refer to, is part of, or includes circuitry capable of sequentially and automatically carrying out a sequence of arithmetic or logical operations; and recording, storing, and/or transferring digital data. The term “processor circuitry” may refer to one or more application processors, one or more baseband processors, a physical central processing unit (CPU), a single-core processor, a dual-core processor, a triple-core processor, a quad-core processor, and/or any other device capable of executing or otherwise operating computer-executable instructions, such as program code, software modules, and/or functional processes.

Furthermore, the various components of the core network may be referred to as “network elements.” The term “network element” may describe a physical or virtualized equipment used to provide wired or wireless communication network services. The term “network element” may be considered synonymous to and/or referred to as a networked computer, networking hardware, network equipment, network node, router, switch, hub, bridge, radio network controller, RAN device, gateway, server, virtualized network function (VNF), network functions virtualization infrastructure (NFVI), and/or the like.

Application circuitry 1505 may include one or more CPU cores and one or more of cache memory, low drop-out voltage regulators (LDOs), interrupt controllers, serial interfaces such as serial peripheral interface (SPI), I2C or universal programmable serial interface module, real time clock (RTC), timer-counters including interval and watchdog timers, general purpose input/output (I/O or IO), memory card controllers such as secure digital (SD/)MultiMediaCard (MMC) or similar, Universal Serial Bus (USB) interfaces, Mobile Industry Processor Interface (MIPI) interfaces and Joint Test Access Group (JTAG) test access ports. As examples, the application circuitry 1505 may include one or more Intel Pentium®, Core®, or Xeon® processor(s); Advanced Micro Devices (AMD) Ryzen® processor(s), Accelerated Processing Units (APUs), or Epyc® processors; and/or the like. In some embodiments, the system 1500 may not utilize application circuitry 1505, and instead may include a special-purpose processor/controller to process IP data received from an EPC or 5GC, for example.

Additionally or alternatively, application circuitry 1505 may include circuitry such as, but not limited to, one or more FPDs such as FPGAs and the like; PLDs such as complex PLDs (CPLDs), high-capacity PLDs (HCPLDs), and the like; ASICs such as structured ASICs and the like; programmable SoCs (PSoCs); and the like. In such embodiments, the circuitry of application circuitry 1505 may comprise logic blocks or logic fabric including other interconnected resources that may be programmed to perform various functions, such as the procedures, methods, functions, etc. of the various embodiments discussed herein. In such embodiments, the circuitry of application circuitry 1505 may include memory cells (e.g., erasable programmable read-only memory (EPROM), electrically erasable programmable read-only memory (EEPROM), flash memory, static memory (e.g., static random-access memory (SRAM), anti-fuses, etc.)) used to store logic blocks, logic fabric, data, etc. in lookup-tables (LUTs) and the like.

The baseband circuitry 1510 may be implemented, for example, as a solder down substrate including one or more integrated circuits, a single packaged integrated circuit soldered to a main circuit board or a multi-chip module containing two or more integrated circuits. Although not shown, baseband circuitry 1510 may comprise one or more digital baseband systems, which may be coupled via an interconnect subsystem to a CPU subsystem, an audio subsystem, and an interface subsystem. The digital baseband subsystems may also be coupled to a digital baseband interface and a mixed-signal baseband subsystem via another interconnect subsystem. Each of the interconnect subsystems may include a bus system, point-to-point connections, network-on-chip (NOC) structures, and/or some other suitable bus or interconnect technology, such as those discussed herein. The audio subsystem may include digital signal processing circuitry, buffer memory, program memory, speech processing accelerator circuitry, data converter circuitry such as analog-to-digital and digital-to-analog converter circuitry, analog circuitry including one or more of amplifiers and filters, and/or other like components. In an aspect of the present disclosure, baseband circuitry 1510 may include protocol processing circuitry with one or more instances of control circuitry (not shown) to provide control functions for the digital baseband circuitry and/or radio frequency circuitry (for example, the RF FEMs 1515).

User interface circuitry 1550 may include one or more user interfaces designed to enable user interaction with the system 1500 or peripheral component interfaces designed to enable peripheral component interaction with the system 1500. User interfaces may include, but are not limited to, one or more physical or virtual buttons (e.g., a reset button), one or more indicators (e.g., light-emitting diodes (LEDs)), a physical keyboard or keypad, a mouse, a touchpad, a touchscreen, speakers or other audio emitting devices, microphones, a printer, a scanner, a headset, a display screen or display device, etc. Peripheral component interfaces may include, but are not limited to, a non-volatile memory port, a USB port, an audio jack, a power supply interface, etc.

The RF FEMs 1515 may comprise a millimeter wave and one or more sub-millimeter wave radio frequency integrated circuits (RFICs). In some implementations, the one or more sub-millimeter wave RFICs may be physically separated from the millimeter wave circuitry. The RFICs may include connections to one or more antennas or antenna arrays, and the RF FEM may be connected to multiple antennas. In alternative implementations, both millimeter wave and sub-millimeter wave radio functions may be implemented in the same physical RF FEM 1515. The RF FEMs 1515 may incorporate both millimeter wave antennas and sub-millimeter wave antennas.

The memory circuitry 1520 may include one or more of volatile memory including dynamic random-access memory (DRAM) and/or synchronous dynamic random-access memory (SDRAM), and nonvolatile memory (NVM) including high-speed electrically erasable memory (commonly referred to as flash memory), phase change random-access memory (PRAM), magnetoresistive random-access memory (MRAM), etc., and may incorporate the three-dimensional (3D) cross-point (XPOINT) memories from Intel® and Micron®. Memory circuitry 1520 may be implemented as one or more of solder down packaged integrated circuits, socketed memory modules and plug-in memory cards.

The PMIC 1525 may include voltage regulators, surge protectors, power alarm detection circuitry, and one or more backup power sources such as a battery or capacitor. The power alarm detection circuitry may detect one or more of brown out (under-voltage) and surge (over-voltage) conditions. The power tee circuitry 1530 may provide for electrical power drawn from a network cable to provide both power supply and data connectivity to the infrastructure equipment 1500 using a single cable.

The network controller circuitry 1535 may provide connectivity to a network using a standard network interface protocol such as Ethernet, Ethernet over GRE Tunnels, Ethernet over Multiprotocol Label Switching (MPLS), or some other suitable protocol. Network connectivity may be provided to/from the infrastructure equipment 1500 via network interface connector 1540 using a physical connection, which may be electrical (commonly referred to as a “copper interconnect”), optical, or wireless. The network controller circuitry 1535 may include one or more dedicated processors and/or FPGAs to communicate using one or more of the aforementioned protocols. In some implementations, the network controller circuitry 1535 may include multiple controllers to provide connectivity to other networks using the same or different protocols.

The positioning circuitry 1545 may include circuitry to receive and decode signals transmitted by one or more navigation satellite constellations of a global navigation satellite system (GNSS). Examples of navigation satellite constellations (or GNSS) may include United States' Global Positioning System (GPS), Russia's Global Navigation System (GLONASS), the European Union's Galileo system, China's BeiDou Navigation Satellite System, a regional navigation system or GNSS augmentation system (e.g., Navigation with Indian Constellation (NAVIC), Japan's Quasi-Zenith Satellite System (QZSS), France's Doppler Orbitography and Radio-positioning Integrated by Satellite (DORIS), etc.), or the like. The positioning circuitry 1545 may comprise various hardware elements (e.g., including hardware devices such as switches, filters, amplifiers, antenna elements, and the like to facilitate the communications over-the-air (OTA) communications) to communicate with components of a positioning network, such as navigation satellite constellation nodes.

Nodes or satellites of the navigation satellite constellation(s) (“GNSS nodes”) may provide positioning services by continuously transmitting or broadcasting GNSS signals along a line of sight, which may be used by GNSS receivers (e.g., positioning circuitry 1545 and/or positioning circuitry implemented by UEs or the like) to determine their GNSS position. The GNSS signals may include a pseudorandom code (e.g., a sequence of ones and zeros) that is known to the GNSS receiver and a message that includes a time of transmission (ToT) of a code epoch (e.g., a defined point in the pseudorandom code sequence) and the GNSS node position at the ToT. The GNSS receivers may monitor/measure the GNSS signals transmitted/broadcasted by a plurality of GNSS nodes (e.g., four or more satellites) and solve various equations to determine a corresponding GNSS position (e.g., a spatial coordinate). The GNSS receivers also implement clocks that are typically less stable and less precise than the atomic clocks of the GNSS nodes, and the GNSS receivers may use the measured GNSS signals to determine the GNSS receivers' deviation from true time (e.g., an offset of the GNSS receiver clock relative to the GNSS node time). In some embodiments, the positioning circuitry 1545 may include a Micro-Technology for Positioning, Navigation, and Timing (Micro-PNT) integrated circuit (IC) that uses a master timing clock to perform position tracking/estimation without GNSS assistance.

The GNSS receivers may measure the time of arrivals (ToAs) of the GNSS signals from the plurality of GNSS nodes according to its own clock. The GNSS receivers may determine time of flight (ToF) values for each received GNSS signal from the ToAs and the ToTs, and then may determine, from the ToFs, a three-dimensional (3D) position and clock deviation. The 3D position may then be converted into a latitude, longitude and altitude. The positioning circuitry 1545 may provide data to application circuitry 1505, which may include one or more of position data or time data. Application circuitry 1505 may use the time data to synchronize operations with other radio base stations (e.g., RAN nodes).

The components shown by FIG. 5 may communicate with one another using interface circuitry. As used herein, the term “interface circuitry” may refer to, is part of, or includes circuitry providing for the exchange of information between two or more components or devices. The term “interface circuitry” may refer to one or more hardware interfaces, for example, buses, input/output (I/O) interfaces, peripheral component interfaces, network interface cards, and/or the like. Any suitable bus technology may be used in various implementations, which may include any number of technologies, including industry standard architecture (ISA), extended ISA (EISA), peripheral component interconnect (PCI), peripheral component interconnect extended (PCIx), PCI express (PCIe), or any number of other technologies. The bus may be a proprietary bus, for example, used in a SoC based system. Other bus systems may be included, such as an I2C interface, an SPI interface, point-to-point interfaces, and a power bus, among others.

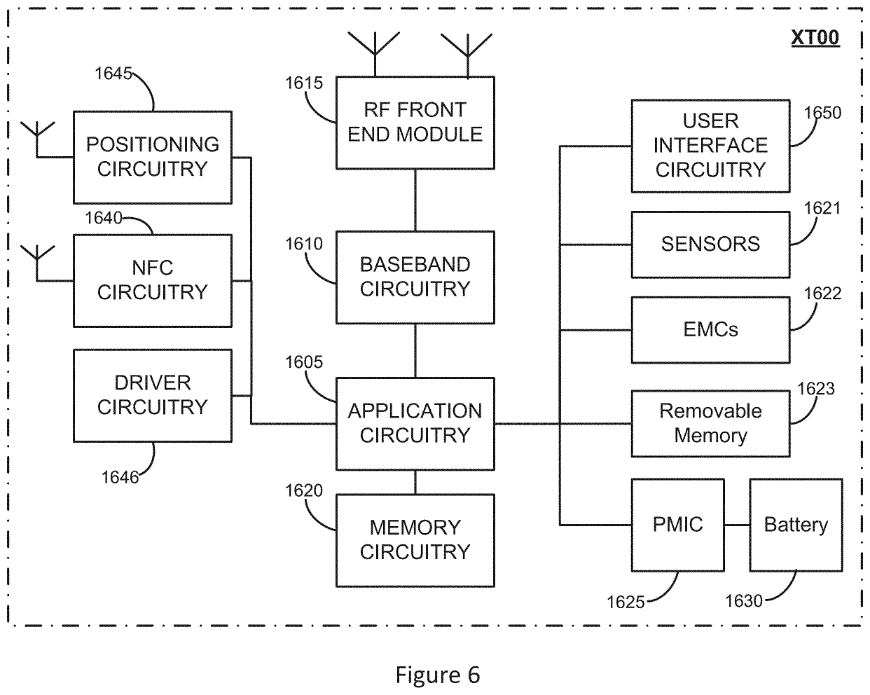

FIG. 6 illustrates an example of a platform 1600 (or “device 1600”) in accordance with various embodiments. In embodiments, the computer platform 1600 may be suitable for use as UEs, application servers, or some other element/device discussed herein. The platform 1600 may include any combinations of the components shown in the example. The components of platform 1600 may be implemented as ICs, portions thereof, discrete electronic devices, or other modules, logic, hardware, software, firmware, or a combination thereof adapted in the computer platform 1600, or as components otherwise incorporated within a chassis of a larger system. The block diagram of FIG. 7 may show a high-level view of components of the system 1500 or platform 1600. However, some of the components shown may be omitted, additional components may be present, and different arrangement of the components shown may occur in other implementations.

The application circuitry 1605 may include circuitry such as, but not limited to single-core or multi-core processors and one or more of cache memory, low drop-out voltage regulators (LDOs), interrupt controllers, serial interfaces such as SPI, inter-integrated circuit (I2C) or universal programmable serial interface circuit, RTC, timer-counters including interval and watchdog timers, general purpose IO, memory card controllers such as secure digital/multimedia card (SD/MMC) or similar, USB interfaces, MIPI interfaces and JTAG test access ports. The processor(s) may include any combination of general-purpose processors and/or dedicated processors (e.g., graphics processors, application processors, etc.). The processors (or cores) may be coupled with or may include memory/storage and may be configured to execute instructions stored in the memory/storage to enable various applications or operating systems to run on the platform 1600. In some embodiments, processors of application circuitry 1505/1605 may process IP data packets received from an EPC or 5GC.

Application circuitry 1605 may be or may include a microprocessor, a multi-core processor, a multithreaded processor, an ultra-low voltage processor, an embedded processor, or other known processing element. In one example, the application circuitry 1605 may include an Intel® Architecture Core based processor, such as a Quark™, an Atom™, an i3, an i5, an i7, or an MCU-class processor, or another such processor available from Intel® Corporation, Santa Clara, Calif. The processors of the application circuitry 1605 may also be one or more of AMD Ryzen® processor(s) or APUs; A5-A9 processor(s) from Apple® Inc., Snapdragon™ processor(s) from Qualcomm® Technologies, Inc., Texas Instruments, Inc.® Open Multimedia Applications Platform (OMAP)™ processor(s); a MIPS-based design from MIPS Technologies, Inc.; an ARM-based design licensed from ARM Holdings, Ltd.; or the like. In some implementations, the application circuitry 1605 may be a part of a SoC in which the application circuitry 1605 and other components are formed into a single integrated circuit, or a single package, such as the Edison™ or Galileo™ SoC boards from Intel® Corporation.

Additionally or alternatively, application circuitry 1605 may include circuitry such as, but not limited to, one or more FPDs such as FPGAs and the like; PLDs such as complex PLDs (CPLDs), high-capacity PLDs (HCPLDs), and the like; ASICs such as structured ASICs and the like; programmable SoCs (PSoCs); and the like. In such embodiments, the circuitry of application circuitry 1605 may comprise logic blocks or logic fabric including other interconnected resources that may be programmed to perform various functions, such as the procedures, methods, functions, etc. of the various embodiments discussed herein. In such embodiments, the circuitry of application circuitry 1605 may include memory cells (e.g., EPROM, EEPROM, flash memory, static memory (e.g., SRAM, anti-fuses, etc.)) used to store logic blocks, logic fabric, data, etc. in lookup-tables (LUTs) and the like.

The baseband circuitry 1610 may be implemented, for example, as a solder down substrate including one or more IC, a single packaged IC soldered to a main circuit board, or a multi-chip module containing two or more IC. Although not shown, baseband circuitry 1610 may comprise one or more digital baseband systems, which may be coupled via an interconnect subsystem to a CPU subsystem, an audio subsystem, and an interface subsystem. The digital baseband subsystems may also be coupled to a digital baseband interface and a mixed-signal baseband subsystem via another interconnect subsystem. Each of the interconnect subsystems may include a bus system, point-to-point connections, NOC structures, and/or some other suitable bus or interconnect technology, such as those discussed herein. The audio subsystem may include digital signal processing circuitry, buffer memory, program memory, speech processing accelerator circuitry, data converter circuitry such as analog-to-digital and digital-to-analog converter circuitry, analog circuitry including one or more of amplifiers and filters, and/or other like components. In an aspect of the present disclosure, baseband circuitry 1610 may include protocol processing circuitry with one or more instances of control circuitry (not shown) to provide control functions for the digital baseband circuitry and/or radio frequency circuitry (for example, the RF FEMs 1615—which may be similar to, and share one or more characteristics of, RF FEM 100).

The RF FEMs 1615 may comprise millimeter wave and one or more sub-millimeter wave RFICs. In some implementations, the one or more sub-millimeter wave RFICs may be physically separated from the millimeter wave circuitry. The RFICs may include connections to one or more antennas or antenna arrays, and the RF FEM may be connected to multiple antennas. In alternative implementations, both millimeter wave and sub-millimeter wave radio functions may be implemented in the same physical RF FEM 1615. The RF FEMs 1615 may incorporate both millimeter wave antennas and sub-millimeter wave antennas.

The memory circuitry 1620 may include any number and type of memory devices used to provide for a given amount of system memory. As examples, the memory circuitry 1620 may include one or more of volatile memory including random-access memory (RAM), dynamic RAM (DRAM) and/or synchronous dynamic RAM (SDRAM), and nonvolatile memory (NVM) including high-speed electrically erasable memory (commonly referred to as flash memory), PRAM, MRAM, etc. The memory circuitry 1620 may be developed in accordance with a Joint Electron Devices Engineering Council (JEDEC) low power double data rate (LPDDR)-based design, such as LPDDR2, LPDDR3, LPDDR4, or the like. Memory circuitry 1620 may be implemented as one or more of solder down packaged IC, single die package (SDP), dual die package (DDP) or quad die package (Q17P), socketed memory modules, dual inline memory modules (DIMMs) including microDIMMs or MiniDIMMs, and/or soldered onto a motherboard via a BGA. In low power implementations, the memory circuitry 1620 may be on-die memory or registers associated with the application circuitry 1605. To provide for persistent storage of information such as data, applications, operating systems and so forth, memory circuitry 1620 may include one or more mass storage devices, which may include, inter alia, a solid state disk drive (SSDD), hard disk drive (HDD), a micro HDD, resistance change memories, phase change memories, holographic memories, or chemical memories, among others. For example, the computer platform 1600 may incorporate the three-dimensional (3D) cross-point (XPOINT) memories from Intel® and Micron®.

Removable memory circuitry 1623 may include devices, circuitry, enclosures/housings, ports or receptacles, etc. used to coupled portable data storage devices with the platform 1600. These portable data storage devices may be used for mass storage purposes, and may include, for example, flash memory cards (e.g., SD cards, microSD cards, xD picture cards, and the like), and USB flash drives, optical discs, external HDDs, and the like.

The platform 1600 may also include interface circuitry (not shown) that is used to connect external devices with the platform 1600. The external devices connected to the platform 1600 via the interface circuitry may include sensors 1621, such as accelerometers, level sensors, flow sensors, temperature sensors, pressure sensors, barometric pressure sensors, and the like. The interface circuitry may be used to connect the platform 1600 to electro-mechanical components (EMCs) 1622, which may allow platform 1600 to change its state, position, and/or orientation, or move or control a mechanism or system. The EMCs 1622 may include one or more power switches, relays including electro-mechanical relays (EMRs) and/or solid state relays (SSRs), actuators (e.g., valve actuators, etc.), an audible sound generator, a visual warning device, motors (e.g., DC motors, stepper motors, etc.), wheels, thrusters, propellers, claws, clamps, hooks, and/or other like electro-mechanical components. In embodiments, platform 1600 may be configured to operate one or more EMCs 1622 based on one or more captured events and/or instructions or control signals received from a service provider and/or various clients.

In some implementations, the interface circuitry may connect the platform 1600 with positioning circuitry 1645, which may be the same or similar as the positioning circuitry 1545 discussed with regard to FIG. 5.

In some implementations, the interface circuitry may connect the platform 1600 with near field communication (NFC) circuitry 1640, which may include an NFC controller coupled with an antenna element and a processing device. The NFC circuitry 1640 may be configured to read electronic tags and/or connect with another NFC-enabled device.

The driver circuitry 1646 may include software and hardware elements that operate to control particular devices that are embedded in the platform 1600, attached to the platform 1600, or otherwise communicatively coupled with the platform 1600. The driver circuitry 1646 may include individual drivers allowing other components of the platform 1600 to interact or control various input/output (I/O) devices that may be present within, or connected to, the platform 1600. For example, driver circuitry 1646 may include a display driver to control and allow access to a display device, a touchscreen driver to control and allow access to a touchscreen interface of the platform 1600, sensor drivers to obtain sensor readings of sensors 1621 and control and allow access to sensors 1621, EMC drivers to obtain actuator positions of the EMCs 1622 and/or control and allow access to the EMCs 1622, a camera driver to control and allow access to an embedded image capture device, audio drivers to control and allow access to one or more audio devices.

The power management integrated circuitry (PMIC) 1625 (also referred to as “power management circuitry 1625”) may manage power provided to various components of the platform 1600. In particular, with respect to the baseband circuitry 1610, the PMIC 1625 may control power-source selection, voltage scaling, battery charging, or DC-to-DC conversion. The PMIC 1625 may often be included when the platform 1600 is capable of being powered by a battery 1630, for example, when the device is included in a UE.

In some embodiments, the PMIC 1625 may control, or otherwise be part of, various power saving mechanisms of the platform 1600. For example, if the platform 1600 is in an RRC_Connected state, where it is still connected to the RAN node as it expects to receive traffic shortly, then it may enter a state known as Discontinuous Reception Mode (DRX) after a period of inactivity. During this state, the platform 1600 may power down for brief intervals of time and thus save power. If there is no data traffic activity for an extended period of time, then the platform 1600 may transition off to an RRC_Idle state, where it disconnects from the network and does not perform operations such as channel quality feedback, handover, etc. The platform 1600 goes into a very low power state and it performs paging where again it periodically wakes up to listen to the network and then powers down again. The platform 1600 may not receive data in this state, in order to receive data, it must transition back to RRC_Connected state. An additional power saving mode may allow a device to be unavailable to the network for periods longer than a paging interval (ranging from seconds to a few hours). During this time, the device is totally unreachable to the network and may power down completely. Any data sent during this time incurs a large delay and it is assumed the delay is acceptable.

A battery 1630 may power the platform 1600, although in some examples the platform 1600 may be mounted deployed in a fixed location, and may have a power supply coupled to an electrical grid. The battery 1630 may be a lithium ion battery, a metal-air battery, such as a zinc-air battery, an aluminum-air battery, a lithium-air battery, and the like. In some implementations, such as in V2X applications, the battery 1630 may be a typical lead-acid automotive battery.

In some implementations, the battery 1630 may be a “smart battery,” which includes or is coupled with a Battery Management System (BMS) or battery monitoring integrated circuitry. The BMS may be included in the platform 1600 to track the state of charge (SoCh) of the battery 1630. The BMS may be used to monitor other parameters of the battery 1630 to provide failure predictions, such as the state of health (SoH) and the state of function (SoF) of the battery 1630. The BMS may communicate the information of the battery 1630 to the application circuitry 1605 or other components of the platform 1600. The BMS may also include an analog-to-digital (ADC) convertor that allows the application circuitry 1605 to directly monitor the voltage of the battery 1630 or the current flow from the battery 1630. The battery parameters may be used to determine actions that the platform 1600 may perform, such as transmission frequency, network operation, sensing frequency, and the like.

A power block, or other power supply coupled to an electrical grid may be coupled with the BMS to charge the battery 1630. In some examples, the power block may be replaced with a wireless power receiver to obtain the power wirelessly, for example, through a loop antenna in the computer platform 1600. In these examples, a wireless battery charging circuit may be included in the BMS. The specific charging circuits chosen may depend on the size of the battery 1630, and thus, the current required. The charging may be performed using the Airfuel standard promulgated by the Airfuel Alliance, the Qi wireless charging standard promulgated by the Wireless Power Consortium, or the Rezence charging standard, promulgated by the Alliance for Wireless Power, among others.

Although not shown, the components of platform 1600 may communicate with one another using a suitable bus technology, which may include any number of technologies, including ISA, extended ISA (EISA), PCI, peripheral component interconnect extended (PCIx), PCI express (PCIe), a Time-Trigger Protocol (TTP) system, or a FlexRay system, or any number of other technologies. The bus may be a proprietary bus, for example, used in a SoC based system. Other bus systems may be included, such as an I2C interface, an SPI interface, point-to-point interfaces, and a power bus, among others.

FIG. 13 illustrates example components of baseband circuitry 1510/1610 and RF FEMs 1515/1615 in accordance with some embodiments. As shown, the RF FEM 1515/1615 may include RF circuitry 1706, FEM circuitry 1708, one or more antennas 1710 coupled together at least as shown.

The baseband circuitry 1510/1610 may include circuitry such as, but not limited to, one or more single-core or multi-core processors. The baseband circuitry 1510/1610 may include one or more baseband processors or control logic to process baseband signals received from a receive signal path of the RF circuitry 1706 and to generate baseband signals for a transmit signal path of the RF circuitry 1706. Baseband processing circuitry 1510/1610 may interface with the application circuitry 1505/1605 for generation and processing of the baseband signals and for controlling operations of the RF circuitry 1706. For example, in some embodiments, the baseband circuitry 1510/1610 may include a third generation (3G) baseband processor 1704A, a fourth generation (4G) baseband processor 1704B, a fifth generation (5G) baseband processor 1704C, or other baseband processor(s) 1704D for other existing generations, generations in development or to be developed in the future (e.g., second generation (2G), sixth generation (6G), etc.). The baseband circuitry 1510/1610 (e.g., one or more of baseband processors 1704A-D) may handle various radio control functions that enable communication with one or more radio networks via the RF circuitry 1706. In other embodiments, some or all of the functionality of baseband processors 1704A-D may be included in modules stored in the memory 1704G and executed via a CPU 1704E. The radio control functions may include, but are not limited to, signal modulation/demodulation, encoding/decoding, radio frequency shifting, etc. In some embodiments, modulation/demodulation circuitry of the baseband circuitry 1510/1610 may include Fast-Fourier Transform (FFT), preceding, or constellation mapping/demapping functionality. In some embodiments, encoding/decoding circuitry of the baseband circuitry 1510/1610 may include convolution, tail-biting convolution, turbo, Viterbi, or Low-Density Parity Check (LDPC) encoder/decoder functionality. Embodiments of modulation/demodulation and encoder/decoder functionality are not limited to these examples and may include other suitable functionality in other embodiments.

In some embodiments, the baseband circuitry 1510/1610 may include one or more audio DSP 1704F. The audio DSP(s) 1704F may be include elements for compression/decompression and echo cancellation and may include other suitable processing elements in other embodiments. Components of the baseband circuitry may be suitably combined in a single chip, a single chipset, or disposed on a same circuit board in some embodiments. In some embodiments, some or all of the constituent components of the baseband circuitry 1510/1610 and the application circuitry 1505/1605 may be implemented together such as, for example, on a SoC.

In some embodiments, the baseband circuitry 1510/1610 may provide for communication compatible with one or more radio technologies. For example, in some embodiments, the baseband circuitry 1510/1610 may support communication with an evolved universal terrestrial radio access network (EUTRAN) or other wireless metropolitan area networks (WMAN), a wireless local area network (WLAN), a wireless personal area network (WPAN). Embodiments in which the baseband circuitry 1510/1610 is configured to support radio communications of more than one wireless protocol may be referred to as multi-mode baseband circuitry.

RF circuitry 1706 may enable communication with wireless networks using modulated electromagnetic radiation through a non-solid medium. In various embodiments, the RF circuitry 1706 may include switches, filters, amplifiers, etc. to facilitate the communication with the wireless network. RF circuitry 1706 may include a receive signal path which may include circuitry to down-convert RF signals received from the FEM circuitry 1608 and provide baseband signals to the baseband circuitry 1510/1610. RF circuitry 1706 may also include a transmit signal path which may include circuitry to up-convert baseband signals provided by the baseband circuitry 1510/1610 and provide RF output signals to the FEM circuitry 1608 for transmission.

In some embodiments, the receive signal path of the RF circuitry 1706 may include mixer circuitry 1706a, amplifier circuitry 1706b and filter circuitry 1706c. In some embodiments, the transmit signal path of the RF circuitry 1706 may include filter circuitry 1706c and mixer circuitry 1706a. RF circuitry 1706 may also include synthesizer circuitry 1706d for synthesizing a frequency for use by the mixer circuitry 1706a of the receive signal path and the transmit signal path. In some embodiments, the mixer circuitry 1706a of the receive signal path may be configured to down-convert RF signals received from the FEM circuitry 1708 based on the synthesized frequency provided by synthesizer circuitry 1706d. The amplifier circuitry 1706b may be configured to amplify the down-converted signals and the filter circuitry 1706c may be a low-pass filter (LPF) or band-pass filter (BPF) configured to remove unwanted signals from the down-converted signals to generate output baseband signals. Output baseband signals may be provided to the baseband circuitry 1510/1610 for further processing. In some embodiments, the output baseband signals may be zero-frequency baseband signals, although this is not a requirement. In some embodiments, mixer circuitry 1706a of the receive signal path may comprise passive mixers, although the scope of the embodiments is not limited in this respect.

In some embodiments, the mixer circuitry 1706a of the transmit signal path may be configured to up-convert input baseband signals based on the synthesized frequency provided by the synthesizer circuitry 1706d to generate RF output signals for the FEM circuitry 1708. The baseband signals may be provided by the baseband circuitry 1510/1610 and may be filtered by filter circuitry 1706c.

In some embodiments, the mixer circuitry 1706a of the receive signal path and the mixer circuitry 1706a of the transmit signal path may include two or more mixers and may be arranged for quadrature downconversion and upconversion, respectively. In some embodiments, the mixer circuitry 1706a of the receive signal path and the mixer circuitry 1706a of the transmit signal path may include two or more mixers and may be arranged for image rejection (e.g., Hartley image rejection). In some embodiments, the mixer circuitry 1706a of the receive signal path and the mixer circuitry 1706a may be arranged for direct downconversion and direct upconversion, respectively. In some embodiments, the mixer circuitry 1706a of the receive signal path and the mixer circuitry 1706a of the transmit signal path may be configured for super-heterodyne operation.

In some embodiments, the output baseband signals and the input baseband signals may be analog baseband signals, although the scope of the embodiments is not limited in this respect. In some alternate embodiments, the output baseband signals and the input baseband signals may be digital baseband signals. In these alternate embodiments, the RF circuitry 1706 may include analog-to-digital converter (ADC) and digital-to-analog converter (DAC) circuitry and the baseband circuitry 1510/1610 may include a digital baseband interface to communicate with the RF circuitry 1706.

In some dual-mode embodiments, a separate radio IC circuitry may be provided for processing signals for each spectrum, although the scope of the embodiments is not limited in this respect.

In some embodiments, the synthesizer circuitry 1706d may be a fractional N synthesizer or a fractional N/N+1 synthesizer, although the scope of the embodiments is not limited in this respect as other types of frequency synthesizers may be suitable. For example, synthesizer circuitry 1706d may be a delta-sigma synthesizer, a frequency multiplier, or a synthesizer comprising a phase-locked loop with a frequency divider.

The synthesizer circuitry 1706d may be configured to synthesize an output frequency for use by the mixer circuitry 1706a of the RF circuitry 1706 based on a frequency input and a divider control input. In some embodiments, the synthesizer circuitry 1706d may be a fractional N/N+1 synthesizer.

In some embodiments, frequency input may be provided by a voltage-controlled oscillator (VCO), although that is not a requirement. Divider control input may be provided by either the baseband circuitry 1510/1610 or the applications processor 1505/1605 depending on the desired output frequency. In some embodiments, a divider control input (e.g., N) may be determined from a look-up table based on a channel indicated by the applications processor 1505/1605.

Synthesizer circuitry 1706d of the RF circuitry 1706 may include a divider, a delay-locked loop (DLL), a multiplexer and a phase accumulator. In some embodiments, the divider may be a dual modulus divider (DMD) and the phase accumulator may be a digital phase accumulator (DPA). In some embodiments, the DMD may be configured to divide the input signal by either N or N+1 (e.g., based on a carry out) to provide a fractional division ratio. In some example embodiments, the DLL may include a set of cascaded, tunable, delay elements, a phase detector, a charge pump and a D-type flip-flop. In these embodiments, the delay elements may be configured to break a VCO period up into Nd equal packets of phase, where Nd is the number of delay elements in the delay line. In this way, the DLL provides negative feedback to help ensure that the total delay through the delay line is one VCO cycle.

In some embodiments, synthesizer circuitry 1706d may be configured to generate a carrier frequency as the output frequency, while in other embodiments, the output frequency may be a multiple of the carrier frequency (e.g., twice the carrier frequency, four times the carrier frequency) and used in conjunction with quadrature generator and divider circuitry to generate multiple signals at the carrier frequency with multiple different phases with respect to each other. In some embodiments, the output frequency may be a LO frequency (fLO). In some embodiments, the RF circuitry 1706 may include an IQ/polar converter.

FEM circuitry 1708 may include a receive signal path which may include circuitry configured to operate on RF signals received from one or more antennas 1710, amplify the received signals and provide the amplified versions of the received signals to the RF circuitry 1706 for further processing. FEM circuitry 1708 may also include a transmit signal path which may include circuitry configured to amplify signals for transmission provided by the RF circuitry 1706 for transmission by one or more of the one or more antennas 1710. In various embodiments, the amplification through the transmit or receive signal paths may be done solely in the RF circuitry 1706, solely in the FEM 1708, or in both the RF circuitry 1706 and the FEM 1708.

In some embodiments, the FEM circuitry 1708 may include a TX/RX switch to switch between transmit mode and receive mode operation. The FEM circuitry may include a receive signal path and a transmit signal path. The receive signal path of the FEM circuitry may include an LNA to amplify received RF signals and provide the amplified received RF signals as an output (e.g., to the RF circuitry 1706). The transmit signal path of the FEM circuitry 1708 may include a PA to amplify input RF signals (e.g., provided by RF circuitry 1706), and one or more filters to generate RF signals for subsequent transmission (e.g., by one or more of the one or more antennas 1710).

Processors of the application circuitry 1505/1605 and processors of the baseband circuitry 1510/1610 may be used to execute elements of one or more instances of a protocol stack. For example, processors of the baseband circuitry 1510/1610, alone or in combination, may be used execute Layer 3, Layer 2, or Layer 1 functionality, while processors of the baseband circuitry 1510/1610 may utilize data (e.g., packet data) received from these layers and further execute Layer 4 functionality (e.g., transmission communication protocol (TCP) and user datagram protocol (UDP) layers). As referred to herein, Layer 3 may comprise a radio resource control (RRC) layer, described in further detail below. As referred to herein, Layer 2 may comprise a medium access control (MAC) layer, a radio link control (RLC) layer, and a packet data convergence protocol (PDCP) layer, described in further detail below. As referred to herein, Layer 1 may comprise a physical (PHY) layer of a UE/RAN node, described in further detail below.

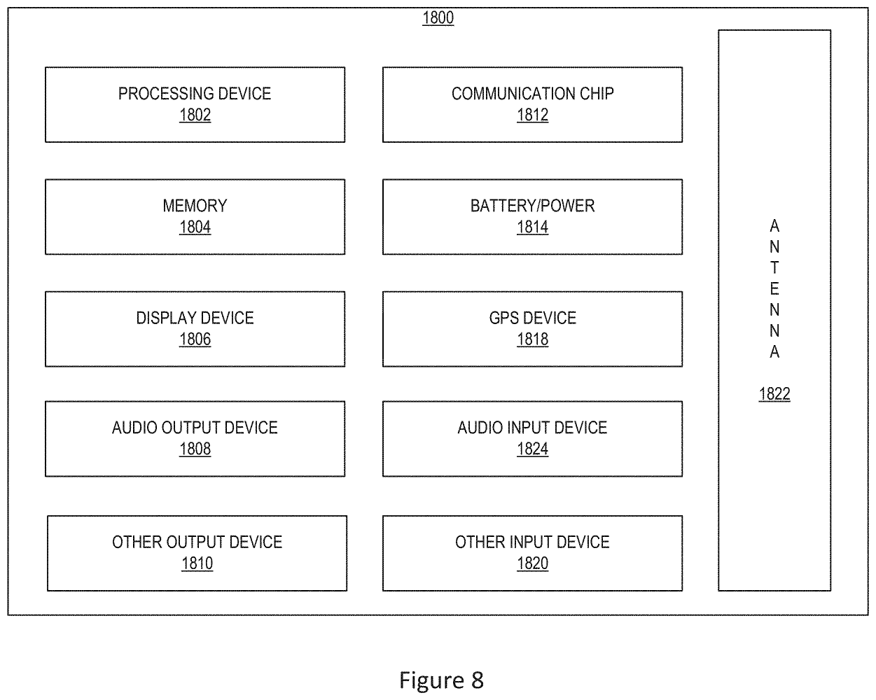

FIG. 8 is a block diagram of an example electrical device 1800 that may include a RF FEM with a filter stack, in accordance with any of the embodiments disclosed herein. For example, any suitable ones of the components of the electrical device 1800 may include one or more of the IC device assemblies 1700, IC packages 1650, platforms 1600, or dies 1502 disclosed herein. A number of components are illustrated in FIG. 8 as included in the electrical device 1800, but any one or more of these components may be omitted or duplicated, as suitable for the application. In some embodiments, some or all of the components included in the electrical device 1800 may be attached to one or more motherboards. In some embodiments, some or all of these components are fabricated onto a single SoC die.

Additionally, in various embodiments, the electrical device 1800 may not include one or more of the components illustrated in FIG. 8, but the electrical device 1800 may include interface circuitry for coupling to the one or more components. For example, the electrical device 1800 may not include a display device 1806, but may include display device interface circuitry (e.g., a connector and driver circuitry) to which a display device 1806 may be coupled. In another set of examples, the electrical device 1800 may not include an audio input device 1824 or an audio output device 1808, but may include audio input or output device interface circuitry (e.g., connectors and supporting circuitry) to which an audio input device 1824 or audio output device 1808 may be coupled.

The electrical device 1800 may include a processing device 1802 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 1802 may include one or more DSPs, ASICs, CPUs, graphics processing units (GPUs), cryptoprocessors (specialized processors that execute cryptographic algorithms within hardware), server processors, or any other suitable processing devices. The electrical device 1800 may include a memory 1804, which may itself include one or more memory devices such as volatile memory (e.g., DRAM), nonvolatile memory (e.g., read-only memory (ROM)), flash memory, solid state memory, and/or a hard drive. In some embodiments, the memory 1804 may include memory that shares a die with the processing device 1802. This memory may be used as cache memory and may include embedded DRAM (eDRAM) or spin transfer torque magnetic RAM (STT-MRAM).

In some embodiments, the electrical device 1800 may include a communication chip 1812 (e.g., one or more communication chips). For example, the communication chip 1812 may be configured for managing wireless communications for the transfer of data to and from the electrical device 1800. The term “wireless” and its derivatives may be used to describe circuits, devices, systems, methods, techniques, communications channels, etc., that may communicate data through the use of modulated electromagnetic radiation through a non-solid medium. The term does not imply that the associated devices do not contain any wires, although in some embodiments they might not.

The communication chip 1812 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 1812 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 1812 may operate in accordance with Enhanced Data for GSM Evolution (EDGE), GSM EDGE RAN (GERAN), Universal Terrestrial RAN (UTRAN), or Evolved UTRAN (E-UTRAN). The communication chip 1812 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 1812 may operate in accordance with other wireless protocols in other embodiments. The electrical device 1800 may include an antenna 1822 to facilitate wireless communications and/or to receive other wireless communications (such as AM or FM radio transmissions).

In some embodiments, the communication chip 1812 may manage wired communications, such as electrical, optical, or any other suitable communication protocols (e.g., the Ethernet). As noted above, the communication chip 1812 may include multiple communication chips. For instance, a first communication chip 1812 may be dedicated to shorter-range wireless communications such as Wi-Fi or Bluetooth, and a second communication chip 1812 may be dedicated to longer-range wireless communications such as GPS, EDGE, GPRS, CDMA, WiMAX, LTE, EV-DO, or others. In some embodiments, a first communication chip 1812 may be dedicated to wireless communications, and a second communication chip 1812 may be dedicated to wired communications.

The electrical device 1800 may include battery/power circuitry 1814. The battery/power circuitry 1814 may include one or more energy storage devices (e.g., batteries or capacitors) and/or circuitry for coupling components of the electrical device 1800 to an energy source separate from the electrical device 1800 (e.g., AC line power).

The electrical device 1800 may include a display device 1806 (or corresponding interface circuitry, as discussed above). The display device 1806 may include any visual indicators, such as a heads-up display, a computer monitor, a projector, a touchscreen display, a liquid crystal display (LCD), a light-emitting diode display, or a flat panel display.

The electrical device 1800 may include an audio output device 1808 (or corresponding interface circuitry, as discussed above). The audio output device 1808 may include any device that generates an audible indicator, such as speakers, headsets, or earbuds.

The electrical device 1800 may include an audio input device 1824 (or corresponding interface circuitry, as discussed above). The audio input device 1824 may include any device that generates a signal representative of a sound, such as microphones, microphone arrays, or digital instruments (e.g., instruments having a musical instrument digital interface (MIDI) output).

The electrical device 1800 may include a GPS device 1818 (or corresponding interface circuitry, as discussed above). The GPS device 1818 may be in communication with a satellite-based system and may receive a location of the electrical device 1800, as known in the art.

The electrical device 1800 may include another output device 1810 (or corresponding interface circuitry, as discussed above). Examples of the other output device 1810 may include an audio codec, a video codec, a printer, a wired or wireless transmitter for providing information to other devices, or an additional storage device.

The electrical device 1800 may include another input device 1820 (or corresponding interface circuitry, as discussed above). Examples of the other input device 1820 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 1800 may have any desired form factor, such as a handheld or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server device or other networked computing component, a printer, a scanner, a monitor, a set-top box, an entertainment control unit, a vehicle control unit, a digital camera, a digital video recorder, or a wearable electrical device. In some embodiments, the electrical device 1800 may be any other electronic device that processes data.

### EXAMPLES OF VARIOUS EMBODIMENTS

Example 1 includes a RF FEM comprising: a first AWR die coupled with a package substrate; and a second AWR die coupled with the first AWR die such that the first AWR die is between the package substrate and the second AWR die.

Example 2 includes the RF FEM of example 1, wherein the second AWR die is coupled with the first AWR die by a connective element that is coupled to the first AWR die and the second AWR die, and the connective element hermetically seals a resonant element of the second AWR die.

Example 3 includes the RF FEM of example 1, further comprising a lid between, and coupled to, the package substrate and the first AWR die.

Example 4 includes the RF FEM of example 3, wherein the lid includes a terminating inductor.

Example 5 includes the RF FEM of example 4, wherein the lid includes an inductor-select switch coupled with the terminating inductor.

Example 6 includes the RF FEM of example 3, wherein the lid includes a band-select switch.

Example 7 includes the RF FEM of example 3, wherein the lid is formed of a non-organic material.

Example 8 includes the RF FEM of any of examples 1-7, wherein the first AWR die is one of a SAW resonator and a FBAR resonator and the second AWR die is the other of the SAW resonator and the FBAR resonator.

Example 9 includes the RF FEM of any of examples 1-7, wherein the RF FEM further includes an active die coupled with, and adjacent to, the first AWR die.

Example 10 includes a RF FEM comprising: a package substrate; a first filter stack coupled with the package substrate, wherein the first filter stack includes: a first AWR die related to a first frequency band; and a second AWR die related to a second frequency band, wherein the first frequency band is different than the second frequency band, and wherein the first AWR die is coupled with the second AWR die, and wherein the first AWR die is between the package substrate and the second AWR die; and an active die coupled with the package substrate adjacent to the first filter stack.

Example 11 includes the RF FEM of example 10, wherein the active die is a PA or an LNA.

Example 12 includes the RF FEM of example 10, wherein the second AWR die includes a resonator element in a space between the first AWR die and the second AWR die.

Example 13 includes the RF FEM of any of examples 10-12, further comprising a seal between, and coupled to, the first AWR die and the second AWR die, wherein the seal hermetically seals a cavity between the first AWR die and the second AWR die.

Example 14 includes the RF FEM of any of examples 10-12, wherein the first filter stack includes a third AWR die related to a third frequency band, wherein the third AWR die is coupled with the second AWR die, and the second AWR die is between the third AWR die and the package substrate.

Example 15 includes the RF FEM of any of examples 10-12, further comprising a second filter stack coupled with the package substrate and adjacent to the active die, wherein the second filter stack includes: a third AWR die related to a third frequency band; and a fourth AWR die related to a fourth frequency band, wherein the third AWR die is coupled with the fourth AWR die such that the third AWR die is between the package substrate and the fourth AWR die.

Example 16 includes the RF FEM of any of examples 10-12, wherein the first filter stack includes: a lid between the package substrate and the first AWR die and the package substrate; and a seal between, and coupled to, the passive lid and the first AWR die, wherein the seal hermetically seals a cavity between the passive lid and the first AWR die.

Example 17 includes the RF FEM of example 16, wherein the lid includes a silicon, silicon nitride, or ceramic substrate.

Example 18 includes a method of forming a RF FEM, wherein the method comprises: coupling an active die to a package substrate; and coupling a first filter stack to the package substrate adjacent to the active die, wherein the first filter stack includes: a first AWR die; and a second AWR die coupled to the first AWR die such that, when the first filter stack is coupled to the package substrate, the first AWR die is between the package substrate and the second AWR die.

Example 19 includes the method of example 18, further comprising coupling a second filter stack to the package substrate adjacent to the active die, wherein the second filter stack includes: a third AWR die; and a fourth AWR die coupled to the third AWR die such that, when the second filter stack is coupled to the package substrate, the third AWR die is between the package substrate and the fourth AWR die.

Example 20 includes the method of examples 18 or 19, wherein a resonating element of the second AWR die is hermetically sealed by a connecting element that connects the first AWR die to the second AWR die.

Various embodiments may include any suitable combination of the above-described embodiments including alternative (or) embodiments of embodiments that are described in conjunctive form (and) above (e.g., the “and” may be “and/or”). Furthermore, some embodiments may include one or more articles of manufacture (e.g., non-transitory computer-readable media) having instructions, stored thereon, that when executed result in actions of any of the above-described embodiments. Moreover, some embodiments may include apparatuses or systems having any suitable means for carrying out the various operations of the above-described embodiments.

The above description of illustrated embodiments, including what is described in the Abstract, is not intended to be exhaustive or limiting as to the precise forms disclosed. While specific implementations of, and examples for, various embodiments or concepts are described herein for illustrative purposes, various equivalent modifications may be possible, as those skilled in the relevant art will recognize. These modifications may be made in light of the above detailed description, the Abstract, the Figures, or the claims.

1. A radio frequency (RF) front-end module (FEM) comprising:
a first acoustic wave resonator (AWR) die coupled with a package substrate; and
a second AWR die coupled with the first AWR die such that the first AWR die is between the package substrate and the second AWR die.

2. The RF FEM of claim 1, wherein the second AWR die is coupled with the first AWR die by a connective element that is coupled to the first AWR die and the second AWR die, and the connective element hermetically seals a resonant element of the second AWR die.

3. The RF FEM of claim 1, further comprising a lid between, and coupled to, the package substrate and the first AWR die.

4. The RF FEM of claim 3, wherein the lid includes a terminating inductor.

5. The RF FEM of claim 4, wherein the lid includes an inductor-select switch coupled with the terminating inductor.

6. The RF FEM of claim 3, wherein the lid includes a band-select switch.

7. The RF FEM of claim 3, wherein the lid is formed of a non-organic material.

8. The RF FEM of claim 1, wherein the first AWR die is one of a surface acoustic wave (SAW) resonator and a thin-film bulk acoustic resonator (FBAR) resonator and the second AWR die is the other of the SAW resonator and the FBAR resonator.

9. The RF FEM of claim 1, wherein the RF FEM further includes an active die coupled with, and adjacent to, the first AWR die.

10. A radio frequency (RF) front-end module (FEM) comprising:
a package substrate;
a first filter stack coupled with the package substrate, wherein the first filter stack includes:
a first acoustic wave resonator (AWR) die related to a first frequency band; and
a second AWR die related to a second frequency band, wherein the first frequency band is different than the second frequency band, and wherein the first AWR die is coupled with the second AWR die, and wherein the first AWR die is between the package substrate and the second AWR die; and
an active die coupled with the package substrate adjacent to the first filter stack.

11. The RF FEM of claim 10, wherein the active die is a power amplifier (PA) or a low-noise amplifier (LNA).

12. The RF FEM of claim 10, wherein the second AWR die includes a resonator element in a space between the first AWR die and the second AWR die.

13. The RF FEM of claim 10, further comprising a seal between, and coupled to, the first AWR die and the second AWR die, wherein the seal hermetically seals a cavity between the first AWR die and the second AWR die.

14. The RF FEM of claim 10, wherein the first filter stack includes a third AWR die related to a third frequency band, wherein the third AWR die is coupled with the second AWR die, and the second AWR die is between the third AWR die and the package substrate.

15. The RF FEM of claim 10, further comprising a second filter stack coupled with the package substrate and adjacent to the active die, wherein the second filter stack includes:
a third AWR die related to a third frequency band; and
a fourth AWR die related to a fourth frequency band, wherein the third AWR die is coupled with the fourth AWR die such that the third AWR die is between the package substrate and the fourth AWR die.

16. The RF FEM of claim 10, wherein the first filter stack includes:
a lid between the package substrate and the first AWR die and the package substrate; and
a seal between, and coupled to, the lid and the first AWR die, wherein the seal hermetically seals a cavity between the lid and the first AWR die.

17. The RF FEM of claim 16, wherein the lid includes a silicon, silicon nitride, or ceramic substrate.

18. A method of forming a radio frequency (RF) front-end module (FEM), wherein the method comprises:
coupling an active die to a package substrate; and
coupling a first filter stack to the package substrate adjacent to the active die, wherein the first filter stack includes:
a first acoustic wave resonator (AWR) die; and
a second AWR die coupled to the first AWR die such that, when the first filter stack is coupled to the package substrate, the first AWR die is between the package substrate and the second AWR die.

19. The method of claim 18, further comprising coupling a second filter stack to the package substrate adjacent to the active die, wherein the second filter stack includes:
a third AWR die; and
a fourth AWR die coupled to the third AWR die such that, when the second filter stack is coupled to the package substrate, the third AWR die is between the package substrate and the fourth AWR die.

20. The method of claim 18, wherein a resonating element of the second AWR die is hermetically sealed by a connecting element that connects the first AWR die to the second AWR die.
